(19) United States
(12) Patent Application Publication
(10) Pub. No.: US 2023/0304964 A1
(43) Pub. Date: Sep. 28, 2023

(54) FET SENSOR USING ANTIOXIDANT

(71) Applicant: KABUSHIKI KAISHA TOSHIBA, Tokyo (JP)

(72) Inventors: Yoshiaki SUGIZAKI, Fujisawa Kanagawa (JP); Hiroko MIKI, Kawasaki Kanagawa (JP)

(73) Assignee: KABUSHIKI KAISHA TOSHIBA, Tokyo (JP)

(21) Appl. No.: 17/930,415

(22) Filed: Sep. 7, 2022

(30) Foreign Application Priority Data
Mar. 22, 2022 (JP) 2022-045444

(51) Int. Cl. G01N 27/414

(52) U.S. Cl. CPC G01N 27/4146; G01N 27/4145; H01L 29/1606

(57) ABSTRACT

According to one embodiment, an FET sensor includes a sensitive film including a carbon allotrope, a liquid film disposed so as to cover the sensitive film, a source electrode and a drain electrode electrically connected to the sensitive film, and a gate electrode configured to apply an electric field to the sensitive film, wherein the liquid film comprises an antioxidant.

### CROSS-REFERENCE TO RELATED APPLICATIONS

This application is based upon and claims the benefit of priority from Japanese Patent Application No. 2022-045444, filed Mar. 22, 2022, the entire contents of which are incorporated herein by reference.

### FIELD

Embodiments described herein relate generally to an FET sensor using an antioxidant.

### BACKGROUND

There is a demand for an FET sensor including a carbon allotrope film as a sensitive film, which can accurately perform measurement even when continuously used.

### BRIEF DESCRIPTION OF THE DRAWINGS

FIG. 1 is a cross-sectional diagram illustrating an example of an FET sensor according to a first embodiment.

Part (a) of FIG. 2 is a schematic diagram illustrating a relationship between a gate voltage and a drain current (that is, “IdVg characteristic”) of an FET sensor including a carbon allotrope film, part (b) of FIG. 2 is a schematic diagram illustrating a shift direction of the IdVg characteristic of the FET sensor when an anion is adsorbed or a cation is adsorbed to the carbon allotrope film, and part (c) of FIG. 2 is a schematic diagram illustrating a shift direction of the IdVg characteristic of the FET sensor when a defect occurs in the carbon allotrope film.

FIG. 3 is a graph showing an IdVg characteristic of an FET sensor including a graphene film, in which a dotted line shows an IdVg characteristic obtained using a buffer solution containing 1 mM of HEPES and 1 mM of KCL, a long and short dash line shows an IdVg characteristic obtained using a buffer solution further containing 1 μM of rhodamine 6G, and a solid line shows an IdVg characteristic obtained using a buffer solution further containing 10 μM of rhodamine 6G.

FIG. 4 is a cross-sectional diagram illustrating an example of an FET sensor of a second embodiment.

FIG. 5 is a flowchart related to a method of using a sensor of a third embodiment.

FIG. 6 is a flowchart relating to a further embodiment of the third embodiment.

FIG. 7 is a plan diagram illustrating a graphene film FET sensor used in Example 1.

FIG. 8 is a graph showing a temporal change in drain current among measurement results of Example 1.

FIG. 9 is a graph showing an IdVg characteristic of the graphene film FET sensor among the measurement results of Example 1.

Part (a) to (c) of FIG. 10 are graphs showing Raman spectra of graphene films obtained in measurement of Example 2, in which part (a) of FIG. 10 relates to measurement results of unmeasured products CH1 and CH2, part (a) of FIG. 10 relates to measurement results of conductivity deteriorated products CH1 to CH3, and part (c) of FIG. 10 relates to measurement results of conductivity deteriorated products CH5 to CH7.

Part (a) to (c) of FIG. 11 are enlarged views near G band (1580 cm⁻¹) and D band (1350 cm⁻¹) among the Raman spectra shown in FIG. 10, in which part (a) of FIG. 11 relates to measurement results of unmeasured products CH1 and CH2, part (b) of FIG. 11 relates to measurement results of conductivity deteriorated products CH1 to CH3, and part (c) of FIG. 11 relates to measurement results of conductivity deteriorated products CH5 to CH7.

Part (a) to (c) of FIG. 12 are enlarged views near 2D band (2700 cm⁻¹) among the Raman spectra shown in FIG. 10, in which part (a) of FIG. 12 relates to measurement results of unmeasured products CH1 and CH2, part (b) of FIG. 12 relates to measurement results of conductivity deteriorated products CH1 to CH3, and part (c) of FIG. 12 relates to measurement results of conductivity deteriorated products CH5 to CH7.

FIG. 13 is a graph showing results of measurement of temporal change in drain current among experimental results of Example 3.

FIG. 14 is a graph showing results of IdVg characteristic measurement among the experimental results of Example 3.

FIG. 15 is a graph showing a work function of graphene obtained by scanning and measuring a gate voltage.

FIG. 16 is a scatter plot of a relationship between a gate voltage and a drain current reduction rate obtained by measurement and calculation of Example 4.

Part (a) to (d) of FIG. 17 are scatter plots of a relationship between a gate voltage and a drain current reduction rate obtained by measurement and calculation in Example 5, in which part (a) of FIG. 17 shows the relationship between the gate voltage and the drain current reduction rate when sodium ascorbate was added as an antioxidant, part (b) of FIG. 17 shows the relationship between the gate voltage and the drain current reduction rate when glutathione was added as an antioxidant, part (c) of FIG. 17 shows the relationship between the gate voltage and the drain current reduction rate when dithiothreitol was added as an antioxidant, and part (d) of FIG. 17 shows the relationship between the gate voltage and the drain current reduction rate when dithiothreitol was added as an antioxidant.

### DETAILED DESCRIPTION

In general, according to one embodiment, there is provided an FET sensor including a carbon allotrope film as a sensitive film, which can accurately perform measurement even when continuously used.

Hereinafter, embodiments will be described with reference to the accompanying drawings. In each embodiment, substantially the same components are denoted by the same reference numerals, and the description thereof may be partially omitted. The drawings are schematic, and a relationship between thickness and planar dimension of each part, a ratio of the thickness of each part and the like may differ from actual ones.

### First Embodiment

### FET Sensor Using Antioxidant

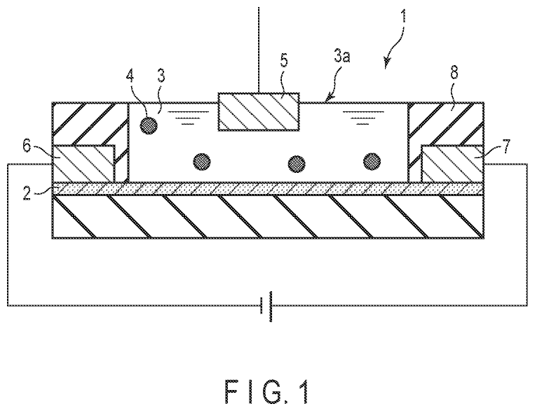

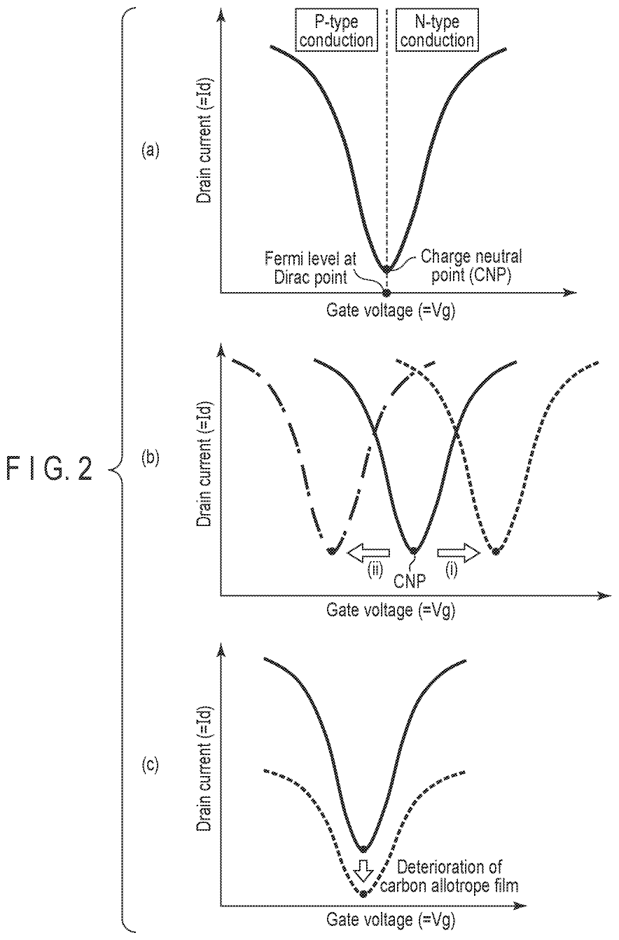

According to a first embodiment, there is provided an FET sensor that detects a target substance using a carbon allotrope film as a sensitive film, that is, a carbon allotrope film FET sensor 1 (hereinafter, referred to as “sensor 1”). As shown in FIG. 1, the sensor 1 includes a carbon allotrope film 2 which is a sensitive film for a target substance, and a liquid film 3 disposed so as to cover the carbon allotrope film 2, and the liquid film 3 contains an antioxidant 4.

A gate electrode 5 is disposed in contact with the carbon allotrope film 2 via the liquid film 3, and a source electrode 6 is electrically connected to one end of the carbon allotrope film 2, and a drain electrode 7 is electrically connected to the other end of the carbon allotrope film 2. Also, a circuit that applies a voltage (that is, a gate voltage) is connected to the gate electrode 5. A circuit for applying a voltage is also formed between the source electrode 6 and the drain electrode 7, and an ammeter (not illustrated) that measures a drain current flowing on the circuit is disposed. The source electrode 6 and the drain electrode 7 are covered with an insulating protective film 8.

The carbon allotrope film 2 is a film made of a substance composed of carbon atoms (that is, a carbon allotrope), and is a film made of, for example, single-layer graphene, laminated graphene, graphite, carbon nanotube, and a combination thereof. In addition, the carbon allotrope film 2 may be configured to be sensitive to the presence of a target substance to be detected, and for example, may be configured such that a probe for capturing the target substance is fixed to the surface of the carbon allotrope film 2, and electrical characteristics of the carbon allotrope film 2 are changed by capturing the target substance with the probe.

The liquid film 3 covers the carbon allotrope film 2. A surface 3a of the liquid film 3 can be disposed so as to be in contact with a specimen sample containing a target substance. In addition, the liquid film 3 is made of a measurement solution that dissolves a sample containing a target substance. As the measurement solution constituting the liquid film 3, for example, water can be selected as a solvent, and any reagents (for example, a stabilizer, a pH adjuster, and the like) necessary for measurement or storage of the sensor 1 may be contained as a solute. In addition, the solvent of the measurement solution may be other than water, and a desired solvent can be selected as long as undesired modification or damage is not caused to the carbon allotrope film 2 and members of the sensor such as the probe.

The antioxidant 4 is a compound having an antioxidant action (hereinafter referred to as “antioxidant substance”) or a composition containing an antioxidant substance. The antioxidant substance constituting the antioxidant 4 may be any substance as long as it has an action of deactivating active oxygen dispersed in a solution, and may be, for example, a thiol compound such as dithiothreitol (that is, DTT) or glutathione, or a reducing agent such as tris(2-carboxyethyl)phosphine (that is, TCEP). Moreover, the antioxidant substance may be, for example, polyphenols such as flavonoids, carotenoids such as α-carotene and β-carotene, enzymes such as peroxidase and catalase, and vitamins such as ascorbic acid and α-tocopherol. The antioxidant 4 may be a compound made of one kind of the antioxidant substances exemplified above, or may be a composition composed of a plurality of kinds of the antioxidant substances. For example, a thiol compound and TCEP can be used in combination as the antioxidant 4. While the antioxidant action of the thiol compound can be gradually reduced by active oxygen generated during use of the sensor 1, the thiol compound is preferable because an antioxidant action of the thiol compound can be restored by TCEP.

As will be described later, the antioxidant 4 can exhibit an effect of preventing deterioration in measurement using the sensor 1. However, as will be described later, this effect is required to exhibit an action of sufficiently deactivating active oxygen dispersed in a solution by the antioxidant 4, and thus it is required to sufficiently secure an antioxidant action by the antioxidant 4. Therefore, from the viewpoint of preventing deterioration of the sensor 1, it is desirable that the antioxidant 4 has a stronger antioxidant action.

It is preferred that the antioxidant 4 is contained in the liquid film 3 at a higher concentration because the antioxidant action of the antioxidant 4 can be enhanced. For example, when the antioxidant 4 is dithiothreitol, the concentration of the dithiothreitol in the liquid film 3 is preferably 1 mM or more.

It is preferable to adjust the pH of the liquid film 3 to a pH suitable for exerting the antioxidant action of the antioxidant 4 because the antioxidant action of the antioxidant 4 can be enhanced. For example, when the antioxidant 4 is dithiothreitol, the pH of the liquid film 3 is preferably 7.0 or more.

Since dispersion of the antioxidant 4 in the solution is promoted as its molecular weight becomes smaller, the antioxidant action of the antioxidant 4 tends to increase. Therefore, when the antioxidant 4 is made of a lower molecular compound, the antioxidant action of the antioxidant 4 can be enhanced, which is preferable. The molecular weight of the antioxidant 4 is preferably, for example, 500 g/mol or less.

On the other hand, it should be noted that when the antioxidant 4 has a strong antioxidant action or has a relatively highly reactive functional group such as a thiol group, there is a possibility of affecting a compound or a member coexisting with the antioxidant 4 in the liquid film 3. For example, when the antioxidant 4 has a thiol group and the compound or member coexisting with the antioxidant 4 is an antibody, enzyme or peptide having a disulfide bond, the thiol group of the antioxidant 4 may cause denaturation, decomposition or the like by eliminating the disulfide bond of the antibody, enzyme or peptide. Therefore, when a compound or member that may be affected as described above is contained in the liquid film 3 of the carbon allotrope film FET sensor 1, the antioxidant 4 is preferably an antioxidant substance having low reactivity with a coexisting substance. For example, when the liquid film 3 of the sensor 1 contains an antibody, enzyme or peptide containing a disulfide bond as described above, for example, ascorbic acid may be used as the antioxidant.

The sensor 1 according to the embodiment detects a substance that can be detected using a conventional carbon allotrope film FET sensor as a target substance. The target substance may be, for example, either a hydrophilic substance or a hydrophobic substance, or may be either a volatile substance or a non-volatile substance. Also, the state of the target substance may be any of a gas, a liquid, and a solid.

When a sample containing a target substance is introduced into the sensor 1 having the configuration of FIG. 1 and the sample is brought into contact with the liquid film 3, the target substance is taken into the liquid film 3. Here, when the target substance is an ionic molecule, the target substance taken into the liquid film 3 is ionized to become positively or negatively charged particles (hereinafter referred to as “charged particles”), and diffuses in the liquid film 3. When the diffused charged particles come into contact with or come close to the carbon allotrope film 2, the electrical characteristics of the carbon allotrope film 2 are changed. Hereinafter, for the sake of simplicity, a case where the target substance is a substance that ionizes in the liquid film 3 will be described as an example, but the target substance may be a substance that does not ionize. For example, the target substance may be a substance that does not ionize but has polarity, or the electrical characteristics of the carbon allotrope film 2 immediately below may be changed by changing the structure when the target substance that does not ionize is captured by an antibody, enzyme, nucleic acid aptamer or peptide.

The carbon allotrope film 2 (particularly, graphene) has unique electrical characteristics, and shows a band structure in which a conduction band and a valence band intersect at one point without having a band gap (this point is referred to as a “Dirac point”). When Fermi level of the carbon allotrope film 2 is equal to the Dirac point, the carrier density is the lowest, so that the electrical resistance of the graphene is the highest. When the Fermi level decreases than the Dirac point, the Fermi level is located in the valence band, and P-type conduction using holes as carriers is exhibited. When the Fermi level further decreases, the density of holes increases, so that the conductivity of graphene is further improved. On the other hand, when the Fermi level of the carbon allotrope film 2 is higher than the Dirac point, the Fermi level is located in the conduction band, so that N-type conduction using electrons as carriers is exhibited. When the Fermi level further increases, the density of electrons increases, and thus the conductivity of graphene is further improved.

The magnitude of the drain current obtained by scanning the sensor 1 including the carbon allotrope film 2 having the characteristics as described above becomes a minimum value when the gate voltage is equal to the Fermi level at the Dirac point, and tends to increase as the gate voltage moves away from the Fermi level at the Dirac point. Such a relationship between the drain current (Id) and the gate voltage (Vg) (hereinafter, referred to as “IdVg characteristic”) can be represented by a V-shaped curve as shown in part (a) of FIG. 2. In addition, a point at which the magnitude of the drain current takes a minimum value on the curve in part (a) of FIG. 2 is referred to as a “charge neutral point (CNP)”.

Here, when negatively charged particles (for example, anions, viruses or the like) approach the surface of the carbon allotrope film 2, a positive charge is attracted to the carbon allotrope film 2 by electrostatic induction, and the Fermi level of the carbon allotrope film 2 decreases. At this time, since the effect of the gate voltage in the positive direction apparently decreases, the V-shaped curve of the IdVg characteristic of the carbon allotrope film is shifted in the high gate voltage direction as shown in (i) of part (b) of FIG. 2. Conversely, when positively charged particles (for example, a cation or the like) approach the surface of the carbon allotrope film 2, the V-shaped curve of the IdVg characteristic shifts in the low gate voltage direction as shown in (ii) of part (b) of FIG. 2. In other words, the shift of the V-shaped curve can also be regarded as a shift of CNP. Therefore, it is possible to detect the presence or absence and the amount of charged particles approaching the carbon allotrope film 2 by observing the shift of the V-shaped curve and CNP of the IdVg characteristic described above in the gate voltage direction.

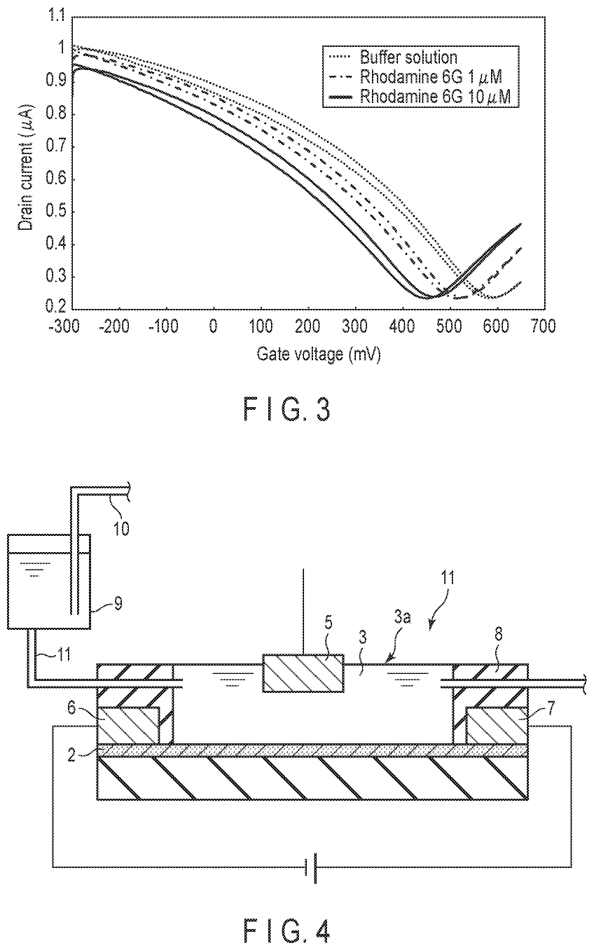

In fact, when the IdVg characteristic is measured using a buffer solution containing 1 mM of HEPES and 1 mM of KCL as a measurement solution constituting the liquid film 3 of the sensor 1 shown in FIG. 1, a V-shaped curve of the solid line in FIG. 3 is observed (in the measurement of the IdVg characteristic, since the gate voltage was continuously reciprocated in the order of −300 mV→+650 mV→−300 mV, FIG. 3 displays measurement results for reciprocation scanning). When a buffer solution containing 1 μM of rhodamine 6G is used, a V-shaped curve indicated by a broken line in FIG. 3 is observed, and when a buffer solution containing 10 μM of rhodamine 6G is used, a V-shaped curve indicated by a long and short dash line in FIG. 3 is observed. Referring to FIG. 3, it is observed that the IdVg characteristic shifts in the low gate voltage direction as the concentration of rhodamine 6G increases. Rhodamine 6G in the liquid film 3 becomes a cation when ionized as shown in the following chemical formula, and thus the result of FIG. 3 supports the above description. Rhodamine 6G approaches or adsorbs to the carbon allotrope film 2 by interaction between n electrons and the carbon allotrope film 2.

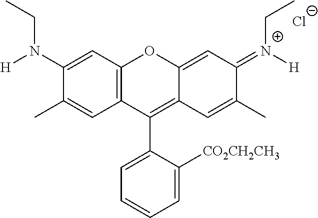

As another measurement method for detecting the presence or absence and the amount of charged particles, for example, there is a method of fixing a gate voltage and measuring a temporal change in drain current. When the gate voltage applied to the sensor 1 is set to a constant value, a substantially constant drain current value is output (with proviso that, it is limited to a case where the carbon allotrope film 2 does not deteriorate and is not affected by the outside of the sensor 1). When the charged particles in the liquid film 3 increase or decrease under influence of the external environment from such a steady state, the drain current changes due to the change in the electrical characteristics of the carbon allotrope film 2. That is, by applying a constant gate voltage and measuring the drain current over time, it is possible to detect that the charged particles derived from the external environment increase or decrease when the drain current changes.

As a further method, the measurement of the temporal change in drain current performed while fixing the gate voltage may be temporarily interrupted a plurality of times at an arbitrary timing, and the gate voltage may be scanned so as to acquire the V-shaped curve and CNP of the IdVg characteristic of the sensor 1 at the time of the temporary interruption.

For example, at each time point before and after exposing the sensor 1 to the external environment, the measurement of the drain current performed while fixing the gate voltage may be temporarily interrupted, and the V-shaped curve and CNP of the IdVg characteristic at each time point may be acquired by scanning the gate voltage. Furthermore, by comparing the positions of the acquired V-shaped curve and CNP before and after exposure to the external environment, it is possible to determine whether the influence of the external environment has caused the shift of the IdVg characteristic in the gate voltage direction. When the V-shaped curve and CNP of the IdVg characteristic are acquired, it is preferable that the influence of the external environment is eliminated. Here, the “exposure to the external environment” is performed, for example, by introducing a sample, and the “elimination of the influence of the external environment” is performed, for example, by replacing a liquid film containing charged particles derived from a sample or a target substance with a specimen liquid not containing the charged particles derived from a sample or a target substance. The temporarily interrupted measurement of the temporal change in drain current can be restarted by returning the gate voltage to the voltage at the time of interruption after the IdVg characteristic measurement.

Here, the inventors have recently found that in a carbon allotrope film FET sensor, deterioration of the carbon allotrope film is promoted by application of a voltage, and a drain current irreversibly decreases. That is, the inventors have found that when a change in electrical characteristics of a carbon allotrope film is observed in measurement using a carbon allotrope film FET sensor, the change may be caused by adsorption of charged particles and/or may be caused by deterioration of the carbon allotrope film. As described above, the adsorption of the charged particles can be determined from the measurement result of the IdVg characteristic of the carbon allotrope film, but the degree of deterioration of the carbon allotrope film can also be determined from the measurement result. Specifically, when the carbon allotrope film is deteriorated, the IdVg characteristic shifted to the low drain current side is observed as shown in part (c) of FIG. 2. This is because, as will be described later, the deterioration of the carbon allotrope film is caused by a defect in the three-dimensional structure of the carbon allotrope, and resistance of the carbon allotrope film increases due to the defect. As can be seen by comparing part (a) and (b) of FIG. 2, the shift direction of the IdVg characteristic is different between the adsorption of the charged particles to the carbon allotrope film and the deterioration of the carbon allotrope film, and thus it is possible to distinguish between both.

As described above, in the measurement using the carbon allotrope film FET sensor, it is important to confirm whether or not the IdVg characteristic is shifted, and when the IdVg characteristic is shifted, it is important to specify the direction. Here, in order to confirm whether the IdVg characteristic is shifted, it is necessary to specify the shape of the V-shaped curve, that is, the position of CNP. That is, the measurement is accompanied by a measurement in a region where the gate voltage exceeds CNP (hereinafter, referred to as “N-type region”). However, the inventors have recently found that the deterioration of the carbon allotrope film is more likely to occur as the gate voltage is higher, and particularly becomes remarkable when the gate voltage reaches the N-type region. That is, it has been found that the sensitivity of the carbon allotrope film decreases and the function of the target substance as a sensor tends to decrease as the measurement in the N-type region is repeated.

Thus, it is required to prevent deterioration of the carbon allotrope film due to application of a voltage, but a deterioration mechanism of the carbon allotrope film and a useful measure therefor have not been proposed. Therefore, it has been difficult to continue accurate sensing by using a conventional carbon allotrope film FET sensor for measurement of a target substance and subjecting to measurement for confirmation of the shift direction of the IdVg characteristic.

However, as described later, the present inventors have recently found that the deterioration of the carbon allotrope film is caused by dissolved oxygen species in the liquid film, and in particular, when a gate voltage having a relatively high voltage is applied to the carbon allotrope film and reaches the N-type region, the dissolved oxygen species in the liquid film is further activated, so that the deterioration of the carbon allotrope film may further progress. According to the discovery of the mechanism, it has been conceived that deterioration of the carbon allotrope film can be reduced by removing active oxygen species dissolved in the liquid film 3. In fact, it has been clarified that by containing the antioxidant 4 in the measurement solution constituting the liquid film 3 of the sensor 1, the shift of the charge neutral point to the low current side in the IdVg characteristic is suppressed, and the deterioration of the carbon allotrope film 2 can be reduced. By reducing the contribution of the deterioration of the carbon allotrope film 2 to the change in the electrical characteristics of the carbon allotrope film 2, it is possible to improve the accuracy of detecting the presence or absence of adsorption of the charged particles and the adsorption amount.

Therefore, it has been difficult to accurately detect the target substance by the conventional carbon allotrope film FET sensor due to deterioration of the carbon allotrope film, but the sensor 1 according to the embodiment can continuously detect the target substance with high accuracy by containing the antioxidant 4 in the liquid film 3 of the sensor 1. In the first embodiment, the configuration in which the sensor 1 includes the liquid film 3 covering the carbon allotrope film 2, and the liquid film 3 contains the antioxidant 4 has been shown. However, this shows the configuration at the time of measurement using the sensor 1, and may be different from the configuration of the sensor to be subjected to measurement (that is, the configuration when the sensor 1 is unused). For example, the unused sensor 1 may be configured such that the sensor 1 does not include the liquid film 3 and the antioxidant 4. In this case, the measurement solution constituting the liquid film 3 and containing antioxidant 4 may be added immediately before use of the sensor 1, so as to cover the carbon allotrope film 2. Moreover, for example, the unused sensor 1 includes the liquid film 3 covering the carbon allotrope film 2, but the liquid film 3 may not contain the antioxidant 4. In this case, the antioxidant 4 may be added to the liquid film 3 immediately before use of the sensor 1. Furthermore, the unused sensor 1 may include, for example, the antioxidant 4 immobilized on the surface of the sensor 1. In this case, the liquid film 3 containing the antioxidant 4 may be formed by adding the measurement solution constituting the liquid film 3 to the surface of the sensor 1 immediately before use of the sensor 1.

### Second Embodiment

A carbon allotrope film FET sensor 1 (hereinafter, referred to as “sensor 1”) according to a second embodiment will be described in detail with reference to FIG. 4. FIG. 4 is a schematic diagram illustrating the sensor 1 according to the second embodiment. In FIG. 4, members similar to those in FIG. 1 described in the first embodiment are denoted by the same reference numerals, and description thereof is omitted.

The sensor 1 according to the second embodiment includes a tank 9 storing a measurement solution constituting a liquid film 3, a flow path 10 connected so as to supply a gas containing no oxidant into the tank 9, and a flow path 11 for supplying the measurement solution in the tank 9 to the liquid film 3 of the sensor 1.

In the first embodiment, it has been described that the deterioration of the carbon allotrope film 2 can be reduced and prevented by removing the dissolved oxygen in the liquid film 3 using the antioxidant, but the removal of the dissolved oxygen in the liquid film 3 can also be performed by supplying a measurement solution in which a gas containing no oxidant is bubbled.

The gas used for bubbling may be an inert gas containing no oxidant, and for example, pure nitrogen gas can be used. The oxidant refers to a compound having an oxidizing action, and is, for example, oxygen.

FIG. 4 shows a mode in which the measurement solution in which a gas containing no oxidant is bubbled is supplied, but bubbling may be performed by immersing a tip of a thin tube in the liquid film 3 and supplying an inert gas, or may be performed by blowing the inert gas onto the surface of the liquid film 3. Bubbling is preferable in that it is possible to remove dissolved oxygen by a relatively easy operation and perform measurement without being affected by a sample, a target substance or the like because an inert gas is used.

As a further embodiment, it is more preferable to combine the use of an antioxidant and the bubbling of an inert gas. Bubbling of the inert gas is a simple and inert method, but the effect may be limited depending on the use of the sensor 1. For example, since it takes a long time of several tens of minutes or more to remove active oxygen by bubbling, it is necessary to perform bubbling before measurement. However, for example, when the use of the sensor 1 is measurement of a target substance in the air, the dissolved oxygen level gradually returns to the original state by dissolving oxygen from the air as a sample, and thus the effect of removing dissolved oxygen by bubbling of an inert gas is temporary. Therefore, if the antioxidant 4 is used in combination, dissolved oxygen can be removed continuously, which is preferable. From a different point of view, the use amount of the antioxidant can be suppressed by the bubbling treatment, which is preferable.

### Third Embodiment

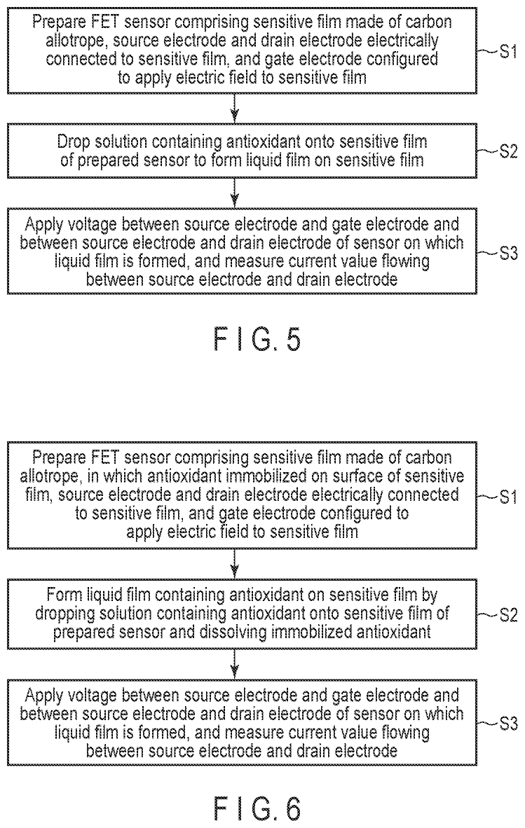

As a third embodiment, a method using an FET sensor is provided. The method for using the FET sensor includes, as shown in FIG. 5, (S1) preparing an FET sensor comprising a sensitive film made of a carbon allotrope, a source electrode and a drain electrode electrically connected to the sensitive film, and a gate electrode configured to apply an electric field to the sensitive film; (S2) dropping a solution containing an antioxidant onto the sensitive film of the sensor prepared in (S1) to form a liquid film on the sensitive film; and (S3) applying a voltage between the source electrode and the gate electrode and between the source electrode and the drain electrode of the sensor on which the liquid film is formed in (S2), and measuring a current value flowing between the source electrode and the drain electrode.

According to the method according to the third embodiment, since the antioxidant is contained in the liquid film of the sensor, accurate detection of the target substance can be continuously performed.

As a further embodiment, a method of using an FET sensor in which an antioxidant is immobilized on a sensitive film is provided. The method includes, as shown in FIG. 6, (S1) preparing an FET sensor including a sensitive film made of a carbon allotrope, in which an antioxidant immobilized on a surface of the sensitive film, a source electrode and a drain electrode electrically connected to the sensitive film, and a gate electrode configured to apply an electric field to the sensitive film; (S2) forming a liquid film containing the antioxidant on the sensitive film by dropping a solution onto the sensitive film of the sensor prepared in (S1) and dissolving the immobilized antioxidant; and (S3) applying a voltage between the source electrode and the gate electrode and between the source electrode and the drain electrode of the sensor on which the liquid film is formed in (S2), and measuring a current value flowing between the source electrode and the drain electrode.

According to the method of a further embodiment, since the antioxidant is immobilized on the sensitive film, a user can omit preparing the solution containing the antioxidant. Therefore, the sensor can be used more easily, which is preferable.

Note that the above-described steps (S1) to (S3) may be continuously performed, or may include any step related to use of the sensor, for example, between the steps.

### EXAMPLES

Hereinafter, the deterioration mechanism of the carbon allotrope film and the effect of inclusion of an antioxidant in the carbon allotrope film FET sensor will be described using experimental data.

### Example 1: Deterioration of Carbon Allotrope Film FET Sensor

### Preparation of Graphene FET Sensor

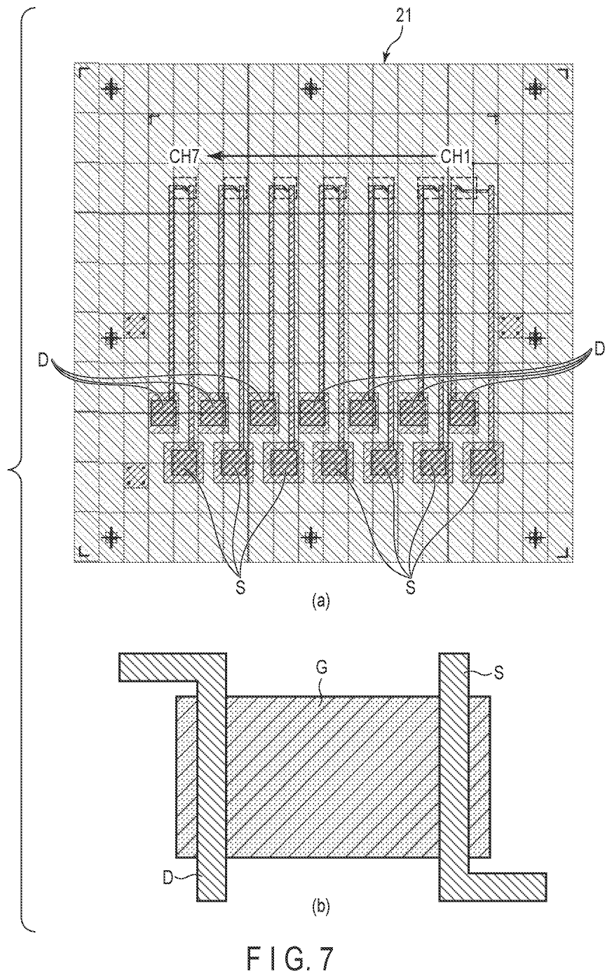

A graphene FET sensor 21 as shown in part (a) of FIG. 7 was prepared. The sensor 21 is a sensor in which FET sensor elements each having a single-layer graphene film as a carbon allotrope film (sensitive film) are disposed for seven channels on one chip. The FET sensor elements in part (a) of FIG. 7 are referred to as CH1, CH2, CH3, CH4, CH5, CH6, and CH7 in order from the right (indicated by an arrow). Part (b) of FIG. 7 is an enlarged view of one of portions surrounded by a broken line in part (a) of FIG. 7 (a structure of a portion surrounded by a broken line is common in CH1 to CH7). Part (b) of FIG. 7 illustrates that a drain electrode D and a source electrode S are electrically connected via a single-layer graphene film G in each FET sensor element.

Among the FET sensor elements used in the measurement of this experiment, a total of six channels excluding CH4 were usable as good products. CH1 to CH7 each include a liquid film covering each graphene film, and the liquid film is disposed over CH1 to CH7 (that is, the liquid film is shared among CH1 to CH7). In Example 1, the liquid film was made of an aqueous solution of 1 mM of 4-(2-hydroxyethyl)-1-piperazineethanesulfonic acid (that is, HEPES) and 4 M of KCl, and the liquid film does not contain an antioxidant.

As shown in FIG. 7, a source electrode and a drain electrode are connected to CH1 to CH7, respectively. Further, gate electrodes are disposed (not illustrated) so that CH1 to CH7 are in contact with the liquid film. In addition, the source electrode and the drain electrode of each of CH1 to CH7 are electrically connected, and the source electrodes S and the drain electrodes D are electrically connected each other. A circuit that applies a common drain voltage between the source electrode S and the drain electrode D is connected to CH1 to CH7, and the gate voltage applied to the gate electrode is commonly applied to CH1 to CH7 via the liquid film, so that voltages of the same magnitude can be applied to CH1 to CH7. In addition, the sensor 21 includes an ammeter (not illustrated) that measures the drain current of each of CH1 to CH7 in each voltage application circuit.

Measurement of temporal change in drain current with stepwise increase of gate voltage

For the graphene FET sensor having the above-described configuration, the temporal change in drain current when the gate voltage was applied was measured. The drain voltage to be applied was set to 5 mV, the gate voltage was set to be constant at +50 mV from the start of measurement to T1, constant at +150 mV from T to T2, constant at +250 mV from T2 to T3, constant at +350 mV from T3 to T4, constant at +450 mV from T4 to T5, and constant at −300 mV from T5 to T6, as shown in Table 1 below. In order to avoid concentration change due to drying of the solution, the same solution is replaced at an intermediate time point of each measurement section.

TABLE 1

| Measurement time | Gate voltage |
|---|---|
| (sec) | (mV) |
| 0 to T1 | +50 |
| T1 to T2 | +150 |
| T2 to T3 | +250 |
| T3 to T4 | +350 |
| T4 to T5 | +450 |
| T5 to T6 | −300 |

As will be described later, the temporal change in drain current was temporarily interrupted at the time points when T1, T2, T3, T4, T5, and T6 are elapsed from the start of the measurement, and the IdVg characteristic of the graphene film at each time point was measured by scanning the gate voltage. After the measurement of the IdVg characteristic at each time point, the gate voltage was rapidly set to the gate voltage in the next measurement period, and the measurement was resumed. As an example, the measurement of the temporal change in drain current with the gate voltage set to +50 mV was temporarily interrupted at time T1, the IdVg characteristic was measured, and then the gate voltage was set to +150 mV, and the measurement of the temporal change in drain current was resumed. At that time, the time point at which the measurement was resumed was defined as time T1.

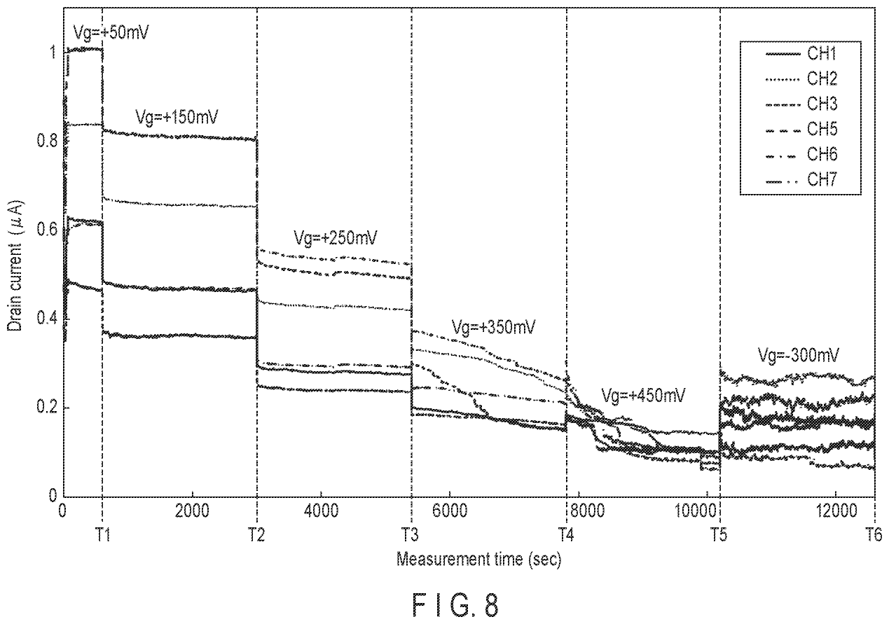

FIG. 8 shows a measurement result of the temporal change in drain current in Example 1. Since there is a tolerance in the performance of components constituting CH1 to CH7, different drain current values were observed for CH1 to CH7, but tendency of the temporal change in drain current indicated by each of CH1 to CH7 is common, and it can be seen that reproducibility of this measurement is high. To describe in detail the tendency of the temporal change in drain current, the drain current gradually decreased with the lapse of time as the gate voltage was set to be as high as +50 mV, +150 mV, and +250 mV. Further, when the gate voltage was set to +350 mV and +450 mV, a significant decrease in drain current was observed. Furthermore, even when the set value of the gate voltage was changed from +450 mV to −300 mV, the value of drain current was about 0.2 μA. Based on the fact that the drain current value when the gate voltage was set to +50 mV was just over 1.0 μA, the results indicated that the conductivity of the graphene film was irreversibly deteriorated.

### Measurement of IdVg Characteristic of Graphene Film

As described above, the measurement of the temporal change in drain current was temporarily interrupted at the time points when T1, T2, T3, T4, T5, and T6 are elapsed after the start of the measurement, and the IdVg characteristic of the graphene film at each time point was measured by scanning the gate voltage. In the measurement of the IdVg characteristic, the drain voltage was set to 5 mV, and the scanning of the gate voltage was performed so that the voltage was increased from −300 mV to +700 mV and then decreased to −300 mV.

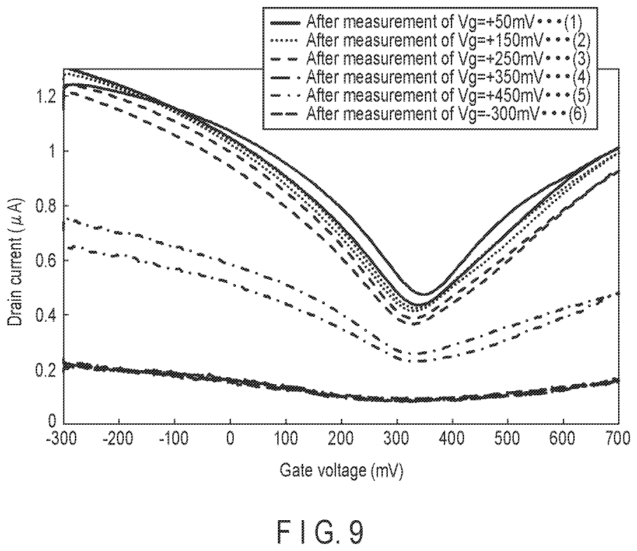

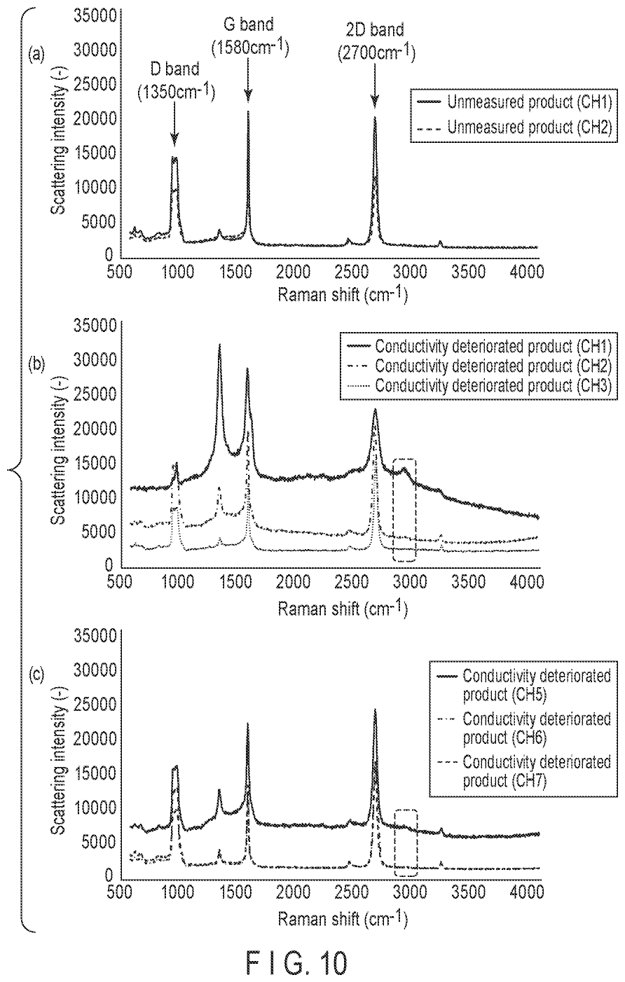

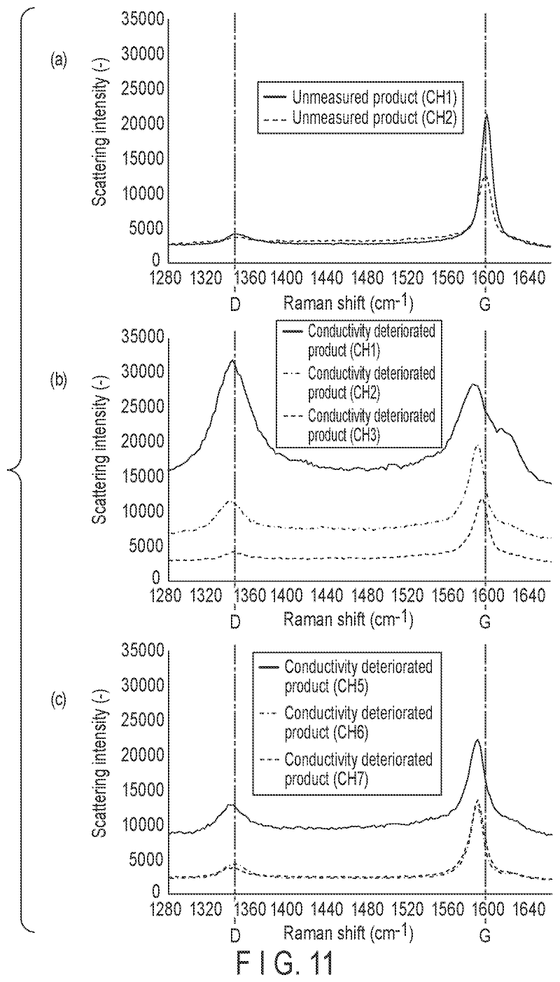

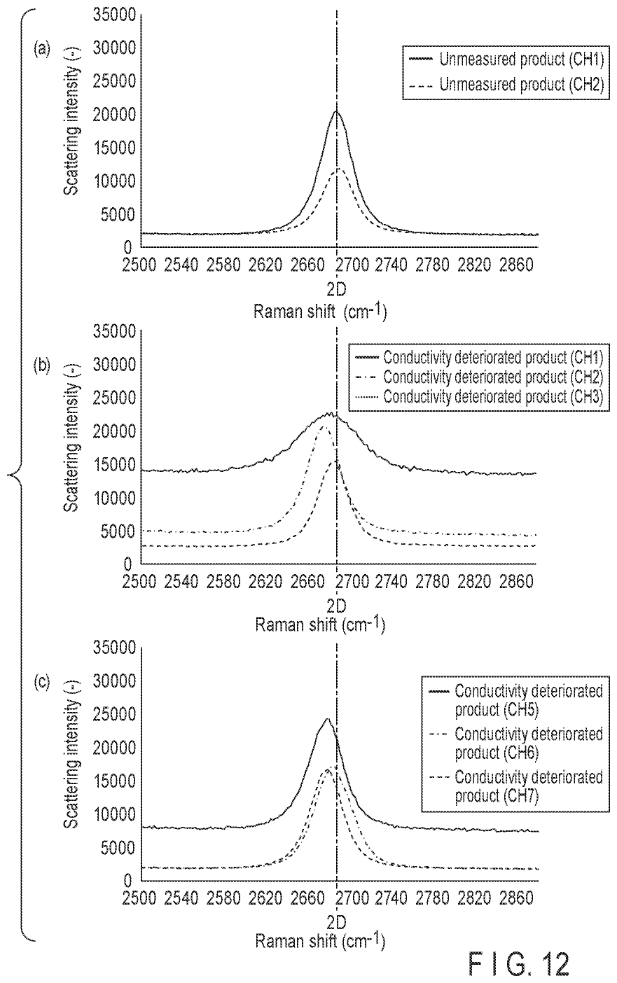

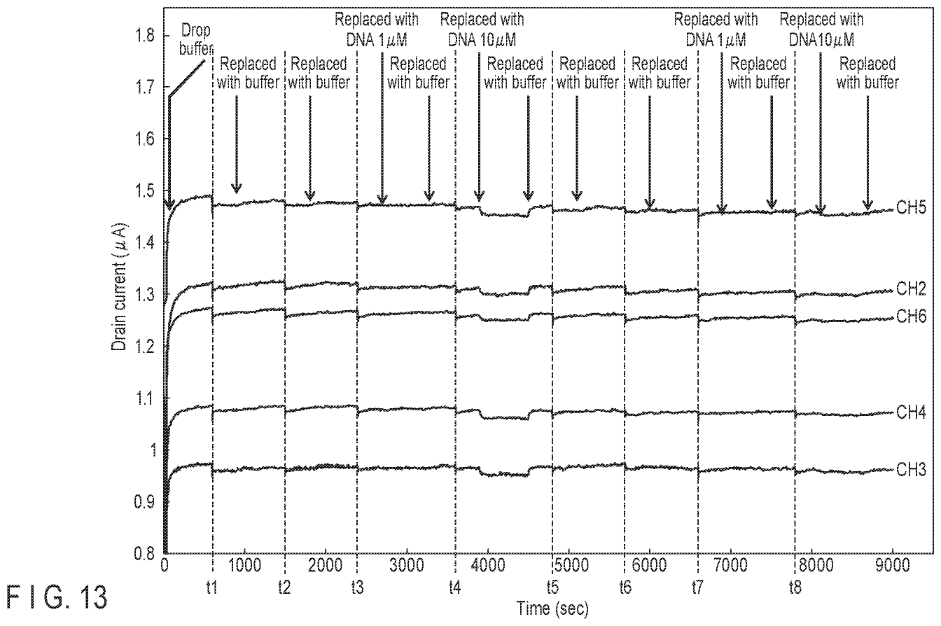

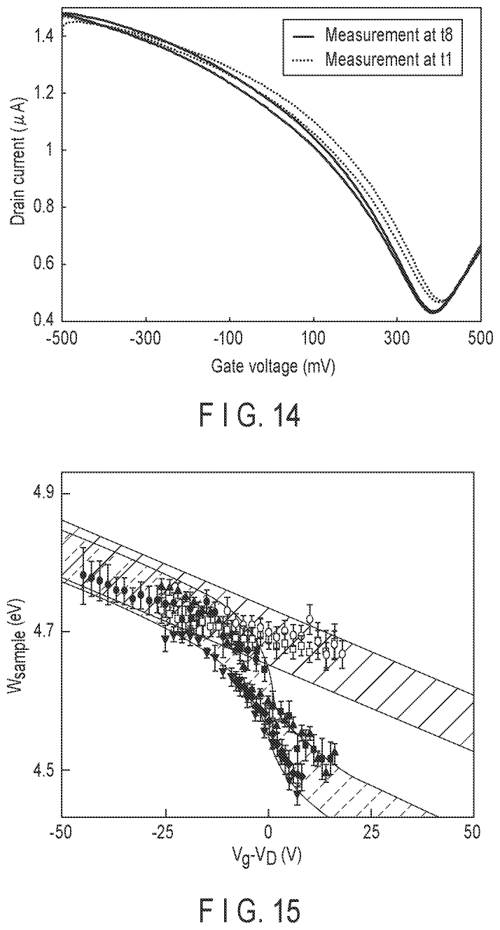

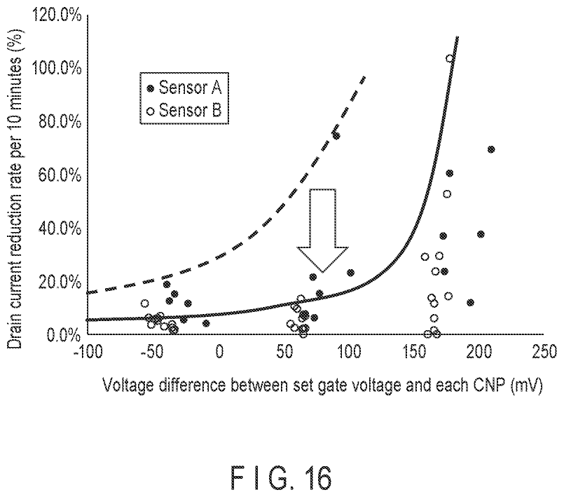

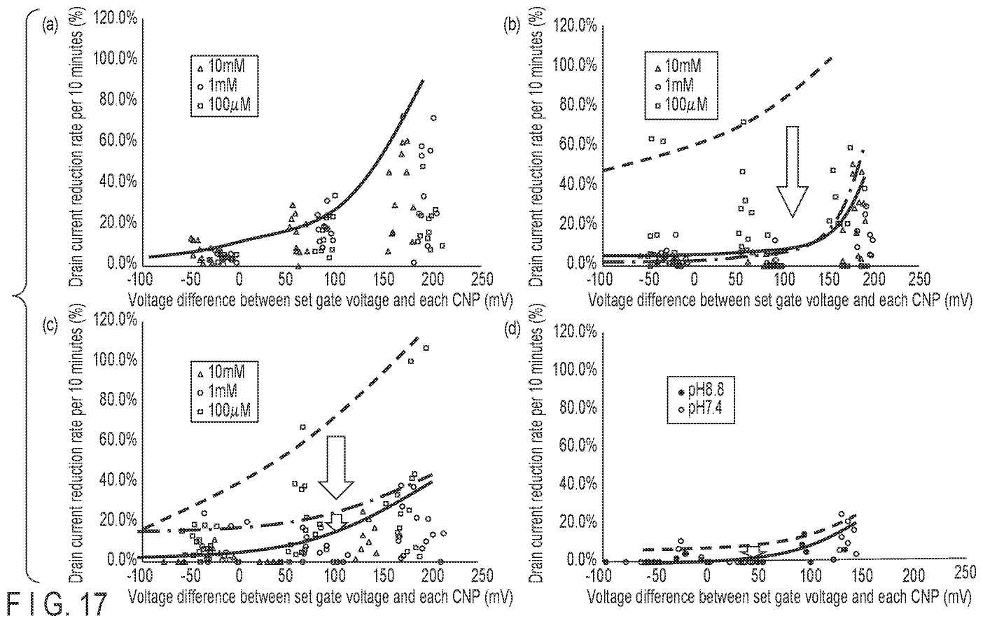

FIG. 9 shows a measurement result of the IdVg characteristic of Example 1. Only the result of CH6 is displayed in order to prevent the figure from being complicated, but similar results are obtained for other CHs. Referring to FIG. 9, as the magnitude of the gate voltage applied in the measurement of the temporal change in drain current increases, the V-shaped curve of the IdVg characteristic was observed to shift in drain current decreasing direction. In particular, the shift of the IdVg characteristic in the drain current decreasing direction observed in the measurement at T4 and T5 was remarkable. In addition, it can be seen that the gate voltages of +350 mV and +450 mV are on the higher voltage side than CNP, that is, in the N-type conduction region. Therefore, when the measurement in the N-type conduction region was performed, it was suggested that the deterioration of the graphene film rapidly progressed. In addition, the gate voltage applied during the period from T5 to T6 in the measurement of the temporal change in drain current was decreased to −300 mV, but no change in the IdVg characteristic at the time point of T5 and the IdVg characteristic at the time point of T6 was observed. That is, the measurement results of the IdVg characteristic also showed that the conductivity of the graphene film was irreversibly deteriorated.

### Example 2: Measurement of Raman Spectra of Graphene Film

After the IdVg characteristic at T6 was measured, Raman spectroscopy was applied to each graphene film included in each sensor element of the sensor elements of CH1 to CH7 shown in Example 1, and a Raman spectrum thereof was measured (hereinafter, CH1 to CH7 after the measurement of the IdVg characteristic at T6 are referred to as “conductivity deteriorated product CH1” to “conductivity deteriorated product CH7”, respectively). In addition, Raman spectroscopic analysis of CH1 and CH2 was applied even for an unmeasured product that was an FET sensor element on the same wafer as the sensor 21 shown in FIG. 7 but was not subjected to the measurement of Example 1, and a Raman spectrum thereof was measured as a control section.

### Results

Part (a) of FIG. 8 shows Raman spectra of graphene films of unmeasured products CH1 and CH2, part (b) of FIG. 8 illustrates Raman spectra of graphene films of conductivity deteriorated products CH1 to CH3, and part (c) of FIG. 8 illustrates Raman spectra of graphene films of conductivity deteriorated products CH5 to CH7.

It is known that the surface property of the graphene film can be confirmed by analyzing a specific Raman spectrum. As compared with the unmeasured products CH1 and CH2, in the conductivity deteriorated products CH1 to CH7, the Raman shift appeared around 2900 cm⁻¹ (indicated by broken lines in part (b) and (c) of FIG. 10) as a new peak, and it was suggested that graphene quality changed.

Part (a) to (c) of FIG. 11 are enlarged views near G band (1580 cm⁻¹) and D band (1350 cm⁻¹) in the Raman spectrum shown in part (a) to (c) of FIG. 10. In the Raman spectroscopic analysis of graphene, the ratio of the D band to the G band is known as an index of the defect amount of graphene. In the conductivity deteriorated products CH1 to CH7, the ratio of the D band was increased as compared with the unmeasured products CH1 and CH2, and it was suggested that defects of graphene increased by the measurement of the temporal change in drain current and the measurement of the IdVg characteristic. In addition, it is known that the widths of the G band and the D band increase as the number of defects of graphene increases. Since the peak widths of the conductivity deteriorated products CH1 to CH7 increase as compared with the unmeasured products CH1 and CH2, it was suggested that the number of defects increases.

Further, as compared with the unmeasured products CH1 and CH2, it can be seen that wavenumbers of the G band and the D band of the conductivity deteriorated products CH1 to CH7 are shifted to the low wavenumber side. This suggests that stress inside the graphene film is reduced. From this suggestion, it is possible to estimate a hypothesis that a defect occurs in the graphene film of the sensor 21 in measurement of electrical characteristics, and the stress remaining inside at the time of forming the graphene film is released by the defect.

Part (a) to (c) of FIG. 12 are graphs in which near 2D band (2700 cm⁻¹) is enlarged and displayed in the Raman spectrum shown in part (a) to (c) of FIG. 10. As compared with the unmeasured products CH1 and CH2, it can be seen that the 2D bands of the conductivity deteriorated products CH1 to CH7 are shifted to the low wavenumber side, and the width is widened. This result also supports the hypothesis described above.

As described above, from the results of Examples of Example 1 and Example 2, it has been confirmed that when electrical characteristics are measured by applying a high gate voltage, particularly a gate voltage to be an N-type region, to the graphene film FET sensor, a defect occurs in the graphene film. This means that, when the temporal change in the electrical characteristics of the graphene film FET sensor is confirmed, even if the IdVg measurement is performed for determining whether the change is caused by the approach of the charged particles or the deterioration of the graphene film, the graphene film may be deteriorated by the measurement itself.

However, the deterioration of the graphene film in the sensor 21 described in Examples 1 and 2 is not caused by repetition of the measurement in the N-type region, but may be caused by application of a high voltage over a long time. Therefore, in Example 3 described below, it was confirmed whether the graphene film was deteriorated even under the condition that the gate voltage applied for a long time was suppressed to be a low voltage and a high voltage was applied only for a short time at the time of IdVg measurement.

### Example 3: Measurement Under Low-Voltage Conditions

In Example 3, in the measurement of the graphene film FET sensor, the application of the high-voltage gate voltage was limited only to the confirmation of the IdVg characteristic of the graphene film, and the measurement of the temporal change in drain current was performed by setting the low-voltage gate voltage.

Specifically, a graphene FET sensor having the same configuration as in Example 1 was prepared, and a gate voltage of −150 mV was applied to measure the temporal change in drain current. In this measurement, a buffer solution constituting a liquid film 3 is replaced with a solution containing 1 μM DNA at the timing after the lapse of time t3 and after the lapse of time t7 from the start of the measurement, and the buffer solution constituting the liquid film 3 is replaced with a solution containing 10 μM DNA at the timing after the lapse of time t4 and after the lapse of time t8 from the start of the measurement. Here, the DNA solution is used for another experimental purpose, and is not intended to have any influence on the deterioration test of the graphene film.

In addition, as in Example 1, the measurement of the temporal change in drain current was interrupted at each time point of times t1 to t8, and the IdVg characteristic at each time point was measured by scanning the gate voltage. Incidentally, the liquid film 3 was replaced with a new buffer solution immediately before each measurement of IdVg characteristic (indicated by arrows in FIG. 13). The IdVg characteristic was measured by scanning to continuously increase the gate voltage from −500 mV to +500 mV and then continuously decrease from +500 mV to −500 mV.

FIG. 13 shows results of the measurement of the temporal change in drain current in Example 3. Referring to FIG. 13, it can be seen that the drain current changes over time for a while from immediately after the start of the experiment in which the liquid film was formed on the graphene FET. This is the time until a solid-liquid interface is stabilized, which is frequently observed in solution-based experiments. Thereafter, it was also observed that the drain current hardly changed except at the time of replacement of the solution and before and after the IdVg measurement. Therefore, it was shown that the defect of the graphene film at the time of measuring the temporal change in drain current can be suppressed to some extent by setting the gate voltage low. In addition, when the buffer solution containing no DNA is replaced with the buffer solution containing DNA, and when the buffer solution containing DNA is replaced with the buffer solution containing no DNA, the drain current is changed. This is caused by the approach of DNA to the graphene film and the change of solution composition.

However, referring to FIG. 13, it can be seen that the drain current decreases before and after the IdVg measurement. Since the amount of decrease is about the same as the change when the buffer solution containing no DNA replaced with the buffer solution containing DNA, it becomes an obstacle to performing accurate measurement.

FIG. 14 shows results of the IdVg characteristic measurement of Example 3. In FIG. 14, a broken line shows a result of IdVg characteristic measured at t1, and a solid line shows a result of IdVg characteristic measured at t8. As a result of the IdVg characteristic measurement of Example 3, it can be seen that the V-shaped curve has gradually shifted to the low drain current side by repetition of the measurement of the IdVg characteristic (only the measurement results at t1 which is the first measurement time and t8 which is the last measurement time are displayed in FIG. 14 so as not to complicate the figure, but similar tendencies are shown for the measurement results at other measurement times). This suggested that a defect occurs in the graphene film of Example 3. Furthermore, since CNP was shifted in the gate voltage direction, it was suggested that when a defect occurred in the graphene film, the defect portion might have a charge.

From FIG. 14, it has been found that the degree of change (that is, the slope) of the drain current with respect to the gate voltage is smaller at the gate voltage (that is, around −350 mV) similar to the gate voltage set for the measurement of the temporal change in drain current than that around CNP. That is, it was shown that the gate voltage was set to be far from CNP, so that the gate voltage dependency of the drain current was reduced. The fact that the gate voltage dependency of the drain current is small means that the change in drain current value is small with respect to the horizontal movement of the V-shaped characteristic when the charged particles are detected, and thus the sensitivity as a sensor is low. Therefore, it has been found that the method of measuring by lowering the gate voltage is not preferable because the sensitivity as a sensor is lowered, and a method of suppressing the defect of the graphene film is necessary even if the gate voltage is set high.

Thus, the reason why the defect occurs in the graphene when the gate voltage is increased, particularly when the gate voltage is increased to exceed CNP to reach the N-type region is considered. FIG. 15 shows a work function of graphene obtained by scanning and measuring the gate voltage. In FIG. 15, the horizontal axis represents a difference of the applied gate voltage from CNP, the vertical axis represents the work function of graphene, hollow points show data of two-layer graphene, and filled points show data of single-layer graphene. The work function of FIG. 15 was measured using scanning Kelvin probe microscopy (SKPM) such that the gate voltage was applied from below a SiO₂ insulating film under the graphene FET. Since the SiO₂ insulating film used in the measurement has a thickness of 300 nm and its dielectric constant is not large, a large voltage is required to change the Fermi level of graphene by electrostatic induction. Therefore, it is presumed that the setting range of the gate voltage shown in FIG. 15 is larger than the setting range shown in FIG. 7, but the modulation range of the Fermi level in the graphene is not largely different in both figures.

Referring to FIG. 15, it can be seen that the work function decreases as the gate voltage is increased. The work function represents energy required for extracting electrons from a substance, and it can be said that as the work function is smaller, electrons are more easily emitted and the electron-donating property is higher. In the single-layer graphene, since the inflection point is around 0 on the horizontal axis, that is, around CNP, it can be seen that the work function rapidly decreases in the N-type region. Therefore, by applying a high gate voltage (particularly, a gate voltage exceeding CNP) to the single-layer graphene, the graphene has an electron-donating property. Since the graphene film used in the measurement of Example 1 was a single layer, it was presumed that the graphene film reaching the N-type region similarly had an electron-donating property in Example 1.

When the graphene film of Example 1 had an electron-donating property, since the measurement of Example 1 was performed in a solution, it is considered that an environment in which active oxygen can be generated by giving electrons to dissolved oxygen in the buffer solution was created. The active oxygen was a highly reactive substance generated by oxygen molecules capturing unpaired electrons, and it was presumed that this active oxygen caused the defect of the graphene film of Example 1.

Example 4: Deterioration Reduction Effect of Graphene Film FET Sensor by Nitrogen Bubbling

In order to confirm whether the dissolved oxygen affects the defect of the graphene film, the following comparative experiment was performed.

As sensors to be subjected to the experiment, a graphene film FET sensor having the same configuration as in Example 1 and a graphene film FET sensor having the same configuration as in Example 1 except for including a buffer solution from which dissolved oxygen was removed by nitrogen bubbling were prepared (hereinafter, the former sensor is referred to as “sensor A”, and the latter sensor is referred to as “sensor B”). The buffer solution was an aqueous solution containing 1 mM of HEPES and 150 mM of KCL, nitrogen bubbling was performed on this buffer solution over 40 minutes, and the buffer solution after nitrogen bubbling was rapidly supplied to the sensor B to perform an experiment.

The deterioration reduction effect of the graphene film FET sensor by nitrogen bubbling was confirmed by measuring the temporal changes in drain currents of the sensor A and the sensor B under the same conditions and comparing the reduction rates of respective drain currents.

More specifically, first, the IdVg characteristic of each of the sensor A and the sensor B before starting the measurement of the temporal change in drain current were measured by the same method as in Example 3. After the IdVg characteristic measurement, a gate voltage about 50 mV lower than CNP was applied to each sensor, and the temporal change in drain current was measured over 5 minutes. Thereafter, in order to prevent the influence of drying, the liquid film was replaced with a new buffer solution, and the temporal change in drain current for 5 minutes was further measured. After measuring the temporal change in drain current, the IdVg characteristic was measured again in the same manner as in Example 3.

Next, the gate voltage applied to each sensor was changed to a value about 50 mV higher than CNP, and the temporal change in drain current and the IdVg characteristic were measured in the same manner as when the gate voltage about 50 mV lower than CNP was applied.

Finally, the gate voltage applied to each sensor was changed to a value about 150 mV higher than CNP, and the temporal change in drain current and the IdVg characteristic were measured in the same manner as when the gate voltage about 50 mV lower than CNP and the gate voltage about 50 mV higher than CNP were applied.

The reduction rate (ΔId) of the drain current in each sensor was calculated by a calculation formula shown in the following formula (1). More specifically, among the values observed in the measurement for 5 minutes, a difference between the value of the drain current at the start of the measurement (Id₁) and the value at the end of the measurement (Id₂) was divided by Id₁ and multiplied by 2 to convert the difference into the reduction rate per 10 minutes.

$$Δ Id = \frac{{Id}_{1} - {Id}_{2}}{{Id}_{1}} \times 2 \qquad ( 1 )$$

Similarly to Examples 1 to 3, each sensor is simultaneously measured using a plurality of FET sensor elements. For this reason, there is a slight variation in the magnitude of the gate voltage at which individual element shows CNP due to the influence of component tolerance, a difference in deterioration degree, and the like. Therefore, for individual element, a voltage difference between the set gate voltage and each CNP is calculated using the value of CNP obtained by the IdVg measurement performed immediately before or immediately after measurement of the temporal change in drain current.

FIG. 16 shows measurement results of Example 4. FIG. 16 is a scatter plot of a relationship between the gate voltage and the drain current reduction rate with the calculation result of the above formula (1) on the vertical axis and the voltage difference between the set gate voltage and each CNP on the horizontal axis. In FIG. 16, filled points show data obtained from each sensor element of the sensor A, hollow points show data obtained from each sensor element of the sensor B, a broken line shows an approximate curve connecting upper ends of dispersion ranges of the filled points, and a solid line shows an approximate curve connecting upper ends of dispersion ranges of the hollow points.

Comparison between the data obtained from the sensor A and the data obtained from the sensor B shows that the drain current reduction rate was suppressed by nitrogen bubbling into the buffer solution. Therefore, the deterioration reduction effect of the graphene film FET sensor by nitrogen bubbling could be confirmed. This result supports that active oxygen causes the defect of the graphene film.

### Example 5: Deterioration Reduction Effect of Carbon Allotrope Film FET Sensor by Antioxidant

Since the defect of the graphene film was considered to be caused by active oxygen, it was expected that an antioxidant having an action of deactivating active oxygen would also exhibit an effect of reducing deterioration of the carbon allotrope film FET sensor. Therefore, the deterioration reduction effect of the carbon allotrope film FET sensor by an antioxidant was confirmed.

As sensors to be subjected to the experiment, the following three kinds of graphene film FET sensors were prepared. Specifically, a graphene film FET sensor having a configuration similar to that of Example 1 except for including a buffer solution containing 100 μM of an antioxidant, a graphene film FET sensor having a configuration similar to that of Example 1 except for including a buffer solution containing 1 mM of an antioxidant, and a graphene film FET sensor having a configuration similar to that of Example 1 except for including a buffer solution containing 10 mM of an antioxidant were prepared. In Example 5, nitrogen bubbling was not performed on the buffer solution supplied to each sensor.

The deterioration reduction effect of the graphene film FET sensor by an antioxidant was confirmed in the same manner as in the method described in Example 4, that is, by measuring the temporal change in drain current of each sensor under the same conditions and comparing the reduction rates of respective drain currents.

FIG. 17 shows experimental results of Example 5. Part (a) of FIG. 17 shows a drain current reduction rate and a voltage difference between the set gate voltage and each CNP when sodium ascorbate was added as the antioxidant. The base of the buffer solution supplied to each sensor is an aqueous solution containing 1 mM of HEPES and 150 mM of KCL (hereinafter referred to as “HEPES base”). As compared with the measurement result of the sensor A shown in FIG. 17, it was shown that the drain current reduction was suppressed by the addition of sodium ascorbate to the HEPES base. However, the concentration dependence of sodium ascorbate was unclear.

Part (b) of FIG. 17 shows results of a similar experiment using glutathione instead of sodium ascorbate as the antioxidant. In part (b) of FIG. 17, a broken line is an approximate curve connecting upper ends of dispersion ranges of 100 μM points, a long and short dash line is an approximate curve connecting upper ends of dispersion ranges of 1 mM points, and a solid line is an approximate curve connecting upper ends of dispersion ranges of 10 mM points. Referring to part (b) of FIG. 17, it can be seen that the drain current reduction rate decreases as the concentration of glutathione increases. Therefore, it was confirmed that the addition of glutathione to the HEPES base showed a deterioration reduction effect of the carbon allotrope film FET sensor, and the effect was concentration-dependent, and a large suppression effect was obtained particularly at a concentration of 1 mM or more. As compared with sodium ascorbate, it is found that glutathione has a stronger suppression effect at a concentration of 1 mM or more.

Since glutathione is a compound having a thiol group exhibiting a strong reducing action, it was presumed that an antioxidant having a thiol group similarly has a deterioration reduction effect of the graphene film FET sensor. Therefore, the similar experiment was performed using dithiothreitol (DTT) instead of glutathione as the antioxidant.

Part (c) of FIG. 17 shows experimental results using DTT instead of glutathione. Referring to part (c) of FIG. 17, DTT showed a deterioration reduction effect of the carbon allotrope film FET sensor similarly to glutathione, and it was confirmed that the effect is concentration-dependent. In addition, it was found that when the concentration was 10 mM, DTT had a greater effect of suppressing the drain current reduction rate rather than glutathione.

Since the thiol group of DTT is further activated in a basic environment, it was expected that the deterioration reduction effect of the carbon allotrope film FET sensor would be improved by the basic environment. Therefore, the base buffer was changed from HEPES base (pH 7.4) to an aqueous solution containing 1 mM of Tris and 150 mM of KCL (pH 8.8), and the DTT concentration was set to 10 mM to perform the similar experiment as described above. Part (d) of FIG. 17D shows results of the experiment. In part (d) of FIG. 17, a broken line is an approximate curve connecting upper ends of dispersion ranges of points at pH 7.4, and a solid line is an approximate curve connecting upper ends of dispersion ranges of points at pH 8.8. According to part (d) of FIG. 17, it has become clear that when the liquid film contains DTT as the antioxidant, the effect of suppressing the drain current reduction rate by DTT can be enhanced by making the liquid film in a more basic environment.

As described above, it was shown that the addition of the antioxidant into the liquid film has an effect of reducing deterioration of the carbon allotrope film FET sensor. Furthermore, since it was considered that this effect was exhibited by deactivating active oxygen dispersed in the solution, and dependency of this effect on the concentration of the antioxidant was confirmed, it was shown that an antioxidant action of the antioxidant in the liquid film is preferably higher.

From the viewpoint of enhancing the antioxidant action of the antioxidant in the liquid film, the antioxidant is preferably a lower molecular compound. This is because lower molecular compounds tend to diffuse more easily in the solution and have a high antioxidant action. Conversely, when the antioxidant is a compound having a molecular weight much greater than that of an oxygen molecule, sufficient movement is not obtained to deactivate small active oxygen dispersed in the solution. In addition, when the molecule is huge, the proportion of the electron-donating group per molecular weight tends to be lower than that of a low molecular weight compound, and the solubility in the liquid decreases as the molecular weight increases, so that the antioxidant action is usually lower than that of the low molecular weight compound.

Regarding the antioxidants used in Example 5, from the fact that the molecular weight of sodium ascorbate was 198 g/mol, that of glutathione was 307 g/mol, and that of DTT was 154 g/mol, it is considered that the molecular weight of the antioxidant is preferably about 500 g/mol at most.

On the other hand, for example, a protein such as an antibody usually contains cysteine (that is, a thiol group) and thus exhibits a slight antioxidant action, but is a huge molecule with a molecular weight exceeding 10,000, and the molecular weight is different from that of active oxygen by 3 orders of magnitude. Furthermore, proteins usually do not have a sufficient proportion of electron-donating groups per molecular weight. Therefore, it is presumed that it is difficult for the protein to exert the similar antioxidant action as 1 mM or more of sodium ascorbate, glutathione, and DTT.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An FET sensor comprising:
a sensitive film comprising a carbon allotrope;
a liquid film disposed so as to cover the sensitive film;
a source electrode and a drain electrode electrically connected to the sensitive film; and
a gate electrode configured to apply an electric field to the sensitive film, wherein the liquid film comprises an antioxidant.

2. The FET sensor according to claim 1, wherein the antioxidant is a compound with a molecular weight of 500 g/mol or less.

3. The FET sensor according to claim 1, wherein the antioxidant is a thiol compound.

4. The FET sensor according to claim 3, wherein the thiol compound is glutathione or dithiothreitol (DTT).

5. The FET sensor according to claim 4, wherein a concentration of the DTT in the liquid film is 1 mM or more, and the liquid film has a pH of 7.0 or more.

6. The FET sensor according to claim 2, wherein the antioxidant is ascorbic acid.

7. The FET sensor according to claim 2, wherein the antioxidant is tris(2-carboxyethyl)phosphine.

8. An FET sensor comprising:
a sensitive film comprising a carbon allotrope;
a source electrode and a drain electrode electrically connected to the sensitive film; and
a gate electrode configured to apply an electric field to the sensitive film,
wherein an antioxidant is immobilized on a surface of the sensitive film.

9. The FET sensor according to claim 1, wherein the sensitive film is single-layer graphene.

10. The FET sensor according to claim 1, wherein the gate electrode is in contact with the liquid film.

11. The FET sensor according to claim 1, further comprising a probe for capturing a target substance on the surface of the sensitive film.

12. A method of using an FET sensor, the method comprising:
preparing an FET sensor comprising a sensitive film comprising a carbon allotrope, a source electrode and a drain electrode electrically connected to the sensitive film, and a gate electrode configured to apply an electric field to the sensitive film;
dropping a solution comprising an antioxidant onto the sensitive film to form a liquid film on the sensitive film;
applying a voltage between the source electrode and the gate electrode and between the source electrode and the drain electrode with respect to the sensor on which the liquid film is formed; and
measuring a current value flowing between the source electrode and the drain electrode.

13. The FET sensor according to claim 8, wherein the sensitive film is single-layer graphene.

14. The FET sensor according to claim 8, wherein the gate electrode is in contact with the liquid film.

15. The FET sensor according to claim 8, further comprising a probe for capturing a target substance on the surface of the sensitive film.
